(19) United States
(12) Patent Application Publication
(10) Pub. No.: US 2017/0033281 A1
(43) Pub. Date: Feb. 2, 2017

(54) Systems and Methods for Implementing Magnetoelectric Junctions Including Integrated Magnetization Components

(71) Applicant: Inston Inc., Santa Monica, CA (US)

(72) Inventor: Qi Hu, Cypress, CA (US)

(73) Assignee: Inston Inc., Santa Monica, CA (US)

(21) Appl. No.: 15/222,871

(22) Filed: Jul. 28, 2016

Related U.S. Application Data
(60) Provisional application No. 62/198,589, filed on Jul. 29, 2015.

(51) Int. Cl. H01L 43/08; H01L 43/10; G11C 11/16; H01L 43/02

(52) U.S. Cl. CPC H01L 43/08; H01L 43/02; H01L 43/10; G11C 11/161

(57) ABSTRACT

Systems and methods in accordance with embodiments of the invention implement magnetoelectric junctions that include integrated magnetization components. In one embodiment, a magnetoelectric junction includes: a first fixed layer; a free layer; a dielectric layer disposed between the first fixed layer and the free layer; at least one magnetization layer that is disposed proximate the free layer; where: the first fixed layer is magnetized in a first direction; the free layer can adopt a magnetization direction that is either substantially parallel with or antiparallel with the first direction; the at least one magnetization layer is magnetized in a second direction that is orthogonal to the first direction; the magnetoelectric junction is characterized by a VCMA coefficient of at least approximately 80 fJ/V·m; and the magnetoelectric junction is configured such that a voltage pulse of a proper length in time can cause the free layer to invert its magnetization direction.

### CROSS-REFERENCE TO RELATED APPLICATIONS

The current application claims priority to U.S. Provisional Application No. 62/198,589, filed Jul. 29, 2015, the disclosure of which is incorporated herein by reference.

### FIELD OF THE INVENTION

The present invention generally relates to the implementation of magnetoelectric junctions.

### BACKGROUND OF THE INVENTION

Devices that rely on electricity and magnetism underlie much of modern electronics. Researchers have recently begun to develop and implement devices that take advantage of both electricity and magnetism in spin-electronic (or so-called “spintronic”) devices. These devices utilize quantum-mechanical magnetoresistance effects, such as giant magnetoresistance (GMR) and tunnel magnetoresistance (TMR). GMR and TMR principles regard how the resistance of a thin film structure that includes alternating layers of ferromagnetic and non-magnetic layers depends upon whether the magnetizations of ferromagnetic layers are in a parallel or antiparallel alignment. For example, magnetoresistive random-access memory (MRAM) is a technology that is being developed that typically utilizes TMR phenomena in providing for alternative random-access memory (RAM) devices. In a typical MRAM bit, data is stored in a magnetic structure that includes two ferromagnetic layers separated by an insulating layer—this structure is conventionally referred to as a magnetic tunnel junction (MTJ). The magnetization of one of the ferromagnetic layers (the fixed layer) is permanently set to a particular direction, while the other ferromagnetic layer (the free layer) can have its magnetization direction free to change. Generally, the MRAM bit can be written by manipulating the magnetization of the free layer such that it is either parallel or antiparallel with the magnetization of the fixed layer; and the bit can be read by measuring its resistance (since the resistance of the bit will depend on whether the magnetizations are in a parallel or antiparallel alignment).

MRAM technologies initially exhibited a number of technological challenges. The first generation of MRAM utilized the Oersted field generated from current in adjacent metal lines to write the magnetization of the free layer, which required a large amount of current to manipulate the magnetization direction of the bit's free layer when the bit size shrinks down to below 100 nm. Thermal assisted MRAM (TA-MRAM) utilizes heating of the magnetic layers in the MRAM bits above the magnetic ordering temperature to reduce the write field. This technology also requires high power consumption and long wire cycles. Spin transfer torque MRAM (STT-MRAM) utilizes the spin-polarized current exerting torque on the magnetization direction in order to reversibly switch the magnetization direction of the free layer. The challenge for STT-MRAM remains that the switching current density needs to be further reduced.

### SUMMARY OF THE INVENTION

Systems and methods in accordance with embodiments of the invention implement magnetoelectric junctions that include integrated magnetization components. In one embodiment, a magnetoelectric junction includes: a first ferromagnetic fixed layer; a ferromagnetic free layer that is magnetically anisotropic; a dielectric layer that is disposed between the first ferromagnetic fixed layer and the ferromagnetic free layer; where: each of the ferromagnetic fixed layer, the ferromagnetic free layer, and the dielectric layer are characterized by a planar surface extruded through a thickness; and the ferromagnetic free layer, the dielectric layer, and the ferromagnetic fixed layer define a stack with an outer surface characterized by its inclusion of the perimeters of said planar surfaces; at least one magnetization layer that is disposed proximate the ferromagnetic free layer; where: the first ferromagnetic fixed layer is magnetized in a first direction; the ferromagnetic free layer can adopt a magnetization direction that is either substantially parallel with or substantially antiparallel with the first direction; the at least one magnetization layer is magnetized in a second direction that is orthogonal to the first direction; the magnetoelectric junction is characterized by a VCMA coefficient of at least approximately 80 fJ/V·m; and the magnetoelectric junction is configured such that a voltage pulse of a proper length in time can cause the ferromagnetic free layer to invert its magnetization direction.

In another embodiment, the ferromagnetic free layer is characterized by perpendicular magnetic anisotropy, and the at least one magnetization layer is characterized by in-plane magnetic anisotropy.

In still another embodiment, the at least one magnetization layer defines a magnetic field that is of sufficient strength to facilitate the precessional switching of the free layer when the voltage pulse of the proper length in time is applied.

In yet another embodiment, the at least one magnetization layer is configured to impose a magnetic field having a strength of between approximately 60 Oe and approximately 1800 Oe.

In still yet another embodiment, the at least one magnetization layer is disposed within a projection of the outer surface of the stack, such that the at least one magnetization layer is aligned with the stack.

In a further embodiment, only a portion of the at least one magnetization layer is disposed within a projection of the outer surface of the stack.

In a still further embodiment, the at least one magnetization layer is disposed entirely outside of a projection of the outer surface of the stack.

In a yet further embodiment, the magnetization layer is substantially coplanar with the stack.

In a still yet further embodiment, the magnetization layer includes one of: CoPt, CoPtCr, and combinations thereof.

In another embodiment, the magnetoelectric junction further includes field insulation.

In still another embodiment, the magnetoelectric junction further includes a cap layer and a seed layer.

In yet another embodiment, at least one of the seed layer and the cap layer includes one of: Molybdenum, Tungsten, Iridium, Bismuth, Rhenium, and Gold.

In still yet another embodiment, at least one of the ferromagnetic fixed layer and the ferromagnetic free layer includes one of: iron, nickel, manganese, cobalt, FeCoB, FeGaB, FePd, FePt, and combinations thereof.

In a further embodiment, the dielectric layer includes one of: MgO and Al₂O₃.

In a still further embodiment, the magnetoelectric junction is characterized by a VCMA coefficient of at least approximately 250 fJ/V·m.

In a yet further embodiment, a magnetoelectric junction includes: a first ferromagnetic fixed layer; a ferromagnetic free layer that is magnetically anisotropic; a dielectric layer that is disposed between the first ferromagnetic fixed layer and the ferromagnetic free layer; an antiferromagnetic layer that is disposed adjacently to the ferromagnetic free layer; where: the first ferromagnetic fixed layer is magnetized in a first direction; the ferromagnetic free layer can adopt a magnetization direction that is either substantially parallel with or substantially antiparallel with the first direction; the magnetoelectric junction is characterized by a VCMA coefficient of at least approximately 80 fJ/V·m; and the magnetoelectric junction is configured such that a voltage pulse of a proper length in time can cause the ferromagnetic free layer to invert its magnetization direction.

In still yet further embodiment, the antiferromagnetic layer includes one of: PtMn, IrMn, and combinations thereof.

In another embodiment, the magnetoelectric junction further includes a cap layer and a seed layer.

In still another embodiment, at least one of the seed layer and the cap layer includes one of: Molybdenum, Tungsten, Iridium, Bismuth, Rhenium, and Gold.

In yet another embodiment, at least one of the ferromagnetic fixed layer and the ferromagnetic free layer includes one of: iron, nickel, manganese, cobalt, FeCoB, FeGaB, FePd, FePt, and combinations thereof.

### BRIEF DESCRIPTION OF THE DRAWINGS

FIGS. 1A-1B illustrates an MEJ configuration that is characterized by perpendicular magnetic anisotropy that can be implemented in accordance with certain embodiments of the invention.

FIG. 2 illustrates an MEJ configuration that is characterized by in-plane magnetic anisotropy that can be implemented in accordance with certain embodiments of the invention.

FIG. 3A illustrates an example of an MEJ, including suitable materials, characterized by out-of-plane magnetization direction of the magnetic free layer, magnetic fixed layer and magnetic pinning layers that can be implemented in accordance with certain embodiments of the invention.

FIG. 3B illustrates another example of an MEJ, including suitable materials, characterized by in-plane magnetization direction of the magnetic free layer, magnetic fixed layer and magnetic pinning layers that can be implemented in accordance with certain embodiments of the invention.

FIGS. 4A and 4B illustrate MEJ configurations that each include a semi-fixed layer that can be implemented in accordance with certain embodiments of the invention.

FIGS. 5A and 5B illustrate typical methods of operation for MEJs.

FIG. 6 illustrates an MEJ having a metal line parallel to and proximate the free layer where current can pass through the metal line and thereby induce spin-orbit torques that can cause the ferromagnetic free layer to adopt a particular magnetization direction.

FIG. 7 illustrates the understood dynamics of precessional switching which can be relied on in the operation of MEJs in accordance with certain embodiments of the invention.

FIG. 8 illustrates the implementation of a plurality of MEJs in accordance with certain embodiments of the invention.

FIG. 9 illustrates an MEJ configuration including an integrated magnetization layer disposed between the free layer and the seed layer in accordance with certain embodiments of the invention.

FIG. 10 illustrates an MEJ configuration including an extended integrated magnetization layer disposed between the free layer and the seed layer in accordance with certain embodiments of the invention.

FIG. 11 illustrates an MEJ configuration including an integrated magnetization layer substantially coplanar with the free layer in accordance with certain embodiments of the invention.

FIG. 12 illustrates an MEJ configuration including an extended integrated magnetization layer substantially coplanar with the stack including the fixed layer, the dielectric layer, the free layer, and the cap layer in accordance with certain embodiments of the invention.

FIG. 13 illustrates an MEJ configuration including an antiferromagnetic layer in accordance with certain embodiments of the invention.

### DETAILED DESCRIPTION

Turning now to the drawings, systems and methods for implementing magnetoelectric junctions including integrated magnetization components are illustrated. Previous efforts at implementing electromagnetic components that utilize magnetoresistance phenomena to achieve two information states (i.e. one bit of information), e.g. magnetic tunnel junctions (MTJs), were largely directed at using a current to manipulate the magnetization configuration (e.g. whether the magnetization directions of the fixed layer and the free layer are parallel or anti-parallel to each other) of the magnetic layers in the device. However, the currents required were often considerably large, particularly in cases where MTJs were used in MRAM configurations. Indeed, in applications that require low-power operation, the requirement of a considerably large current made the implementation of devices that rely on MTJs less commercially viable. Accordingly, voltage-controlled magnetic anisotropy-based MTJs (VMTJs) that generally allow MTJs to utilize an electric field to facilitate the switching of the magnetization direction of the free layer (i.e., ‘write’ to it) as opposed to (or in some cases, in addition to) entirely using a current to do so were developed and reported. See e.g., International Patent Application Number PCT/U52012/038693, entitled “Voltage-Controlled Magnetic Anisotropy (VCMA) Switch and Magneto-electric Memory (MERAM),” by Khalili Amiri et al., the disclosure of which is herein incorporated by reference in its entirety, especially as it pertains to MTJs that rely on VCMA phenomena during their normal operation. See also, “Voltage-Controlled Magnetic Anisotropy in Spintronic Devices,” by Khalili Amiri et al., SPIN, Vol. 2, No. 3 (2012), the disclosure of which is hereby incorporated by reference, especially as it pertains to devices that harness VCMA phenomena. Generally, the coercivity of the free layer of a VMTJ can be reduced using voltage-controlled magnetic anisotropy (VCMA) phenomena, thereby making the free layer more easily switched to the opposite direction (‘writeable’). It has been demonstrated that such devices employing VCMA principles result in marked performance improvements over conventional MTJs. Note that in the instant application, the term ‘magnetoelectric junction’ (MEJ) is used to refer to devices that are configured to viably use VCMA principles to help them realize two distinct information states, e.g. voltage-controlled magnetic anisotropy-based MTJs (VMTJs) as well as the VCMA switches disclosed in International Patent Application Number PCT/US2012/038693, cited above.

In many instances, a fundamental MEJ includes a ferromagnetic fixed layer, a ferromagnetic free layer, and a dielectric layer interposed between said ferromagnetic fixed layer and ferromagnetic free layer. The ferromagnetic fixed layer generally has a fixed magnetization direction, whereas the ferromagnetic free layer can adopt a magnetization direction that is either substantially parallel with or antiparallel with the ferromagnetic fixed magnetization direction. In many instances, the application of a potential difference across the MEJ invokes VCMA phenomena to an impactful extent and thereby allows the free layer to be more easily ‘switched’ in a desired direction (i.e. the direction of magnetization can be defined as desired, e.g. either substantially parallel with or antiparallel with the magnetization of the fixed layer); thus, the free layer can adopt a magnetization direction either parallel with or antiparallel with the magnetization direction of the fixed magnet. In accordance with tunnel magnetoresistance (“TMR”) principles, the resistance of the MEJ will vary depending upon whether the free layer adopts a parallel or an antiparallel magnetization direction relative to the fixed layer, and therefore, the MEJ can define two information states (i.e. one bit of information). An MEJ can thereby be ‘read,’ i.e. whether its ferromagnetic layers have magnetization directions that are parallel or antiparallel can be determined by measuring the resistance across it. Thus, it can be seen that generally, VCMA phenomena can be used to facilitate ‘writing’ to an MEJ, while TMR effects are implicated in the ‘reading’ of the bit.

While MEJs demonstrate much promise, their potential applications continue to be explored. For example, U.S. Pat. No. 8,841,739 (the '739 patent) to Khalili Amiri et al. discloses DIOMEJ cells that utilize diodes (e.g. as opposed to transistors) as access devices to MEJs. As discussed in the '739 patent, using diodes as access devices for MEJs can confer a number of advantages and thereby make the implementation of MEJs much more practicable. The disclosure of the '739 patent is hereby incorporated by reference in its entirety, especially as it pertains to implementing diodes as access devices for MEJs. Furthermore, U.S. Pat. No. 9,099,641 (“the '641 patent”) to Khalili Amiri et al. discloses MEJ configurations that demonstrate improved writeability and readability, and further make the implementation of MEJs more practicable. The disclosure of the '641 patent is hereby incorporated by reference in its entirety, especially as it pertains to MEJ configurations that demonstrate improved writeability and readability. Additionally, U.S. patent application Ser. No. 14/681,358 (“the '358 patent application”) to Qi Hu discloses implementing MEJ configurations that incorporate piezoelectric materials to strain the respective MEJs during operation, and thereby improve performance. The disclosure of the '358 patent application is hereby incorporated by reference in its entirety, especially as it pertains to MEJ configurations that incorporate elements configured to strain the respective MEJs during operation, and thereby improve performance. Further, U.S. patent application Ser. No. 15/044,888 (“the '888 patent application”) to Qi Hu discloses particularly effective materials from which seed and capping layers can be fabricated from in developing MEJs. The disclosure of the '888 patent application is hereby incorporated by reference in its entirety, especially as it pertains to the implementation of Molybdenum, Tungsten, Iridium, Bismuth, Rhenium, and/or Gold within seed/capping layers of MEJs.

While much progress has been made with respect to the development of MEJ configurations, their full potential has yet to be explored. For example, conventional MEJs still often rely on an external means (e.g. a permanent magnet or electric coil) for switching (or defining) a magnetization direction for the free layer (e.g. when its coercivity is reduced). However, having to rely on such external means can be cumbersome, and can undesirably introduce structural complexity, which in turn can introduce manufacturing error. The instant application discloses a number of MEJ configurations that include integrated magnetization components that can facilitate switching (and defining) the magnetization direction for the free layer. In this way, the MEJ can be more self-reliant, and subsequently more practicable/effective. Such configurations will be described in greater detail below. But first, fundamental MEJ structures and their operating principles are now discussed in greater detail.

### Fundamental Magnetoelectric Junction Structures

A fundamental MEJ structure typically includes a ferromagnetic (FM) fixed layer, a FM free layer that has a uniaxial anisotropy (for simplicity, the terms “FM fixed layer” and “fixed layer” will be considered equivalent throughout this application, unless otherwise stated; similarly, the terms “FM free layer”, “ferromagnetic free layer,” “free layer that has a uniaxial anisotropy”, and “free layer” will also be considered equivalent throughout this application, unless otherwise stated), and a dielectric layer separating the FM fixed layer and FM free layer. Generally, the FM fixed layer has a fixed magnetization direction, i.e. the direction of magnetization of the FM fixed layer does not change during the normal operation of the MEJ. Conversely, the FM free layer can adopt a magnetization direction that is either substantially parallel with or antiparallel with the FM fixed layer, i.e. during the normal operation of the MEJ, the direction of magnetization can be made to change. For example, the FM free layer may have a magnetic uniaxial anisotropy, whereby it has an easy axis that is substantially aligned with the direction of magnetization of the FM fixed layer. The easy axis refers to the axis along which the magnetization direction of the layer prefers to align. In other words, an easy axis is an energetically favorable direction (axis) of spontaneous magnetization that is determined by various sources of magnetic anisotropy including, but not limited to, magnetocrystalline anisotropy, magnetoelastic anisotropy, geometric shape of the layer, etc. Relatedly, an easy plane is a plane whereby the direction of magnetization is favored to be within the plane, although there is no bias toward a particular axis within the plane. The easy axis and the direction of the magnetization of the fixed layer can be considered to be ‘substantially aligned’ when—in the case where the magnetization direction of the free layer conforms to the easy axis—the underlying principles of magnetoresistance take effect and result in a distinct measurable difference in the resistance of the MEJ as between when the magnetization directions of the FM layers are substantially parallel relative to when they are substantially antiparallel, e.g. such that two distinct information states can be defined. Similarly, the magnetization directions of the fixed layer and the free layer can be considered to be substantially parallel/antiparallel when the underlying principles of magnetoresistance take effect and result in a distinct measurable difference in the resistance of the MEJ as between the two states (i.e. substantially parallel and substantially antiparallel).

VCMA phenomena can be relied on in switching the FM free layer's characteristic magnetization direction, e.g. the MEJ can be configured such that the application of a potential difference across the MEJ can reduce the coercivity of the free layer, which can allow the free layer's magnetization direction to be switched more easily. For example, with a reduced coercivity, the FM free layer can be subject to magnetization that can make it substantially parallel with or substantially antiparallel with the direction of the magnetization for the FM fixed layer. VCMA phenomena can also be harnessed in this context via precessional switching, whereby subjecting the MEJ to voltage pulses of a precise duration, the magnetization direction can be encouraged to change. A more involved discussion regarding the general operating principles of an MEJ is presented in the following section.

Importantly, the considerations for structuring an MEJ can be understood by reviewing, e.g., “Low-power non-volatile spintronic memory: STT-RAM and beyond”, by K. L. Wang et al., J. Phys. D: Appl. Phys. 46 (2013) 074003, the disclosure of which is hereby incorporated by reference in its entirety. For example, one of the parameters relevant to the characterization of a magnetoelectric-based memory (e.g. MeRAM) is the amount of effective magnetic field H_{eff} generated per unit of applied voltage V or electric field E. Thus, a larger magnetoelectric coefficient H_{eff}/V or H_{eff}/E could result in smaller switching voltage and energy for a respective memory cell. The voltage required for switching in an MEJ should be small enough compared with the breakdown voltage of the junction for reliable operation. Conventional MTJs can have a resistance-area (“RA”) product of 3.5 Ω·μm²; such devices have been measured to sustain >10¹⁶ pulses ˜0.5 V at 5 ns. In general, the RA product for conventional MTJs are often within a range of between approximately 1 Ω·μm² and approximately 20 Ω·μm²; this typically corresponds with a tunnel barrier thickness (e.g. an MgO tunnel barrier thickness) of less than 1 nm. By contrast, the RA product for many MEJs is orders of magnitude larger, e.g. between approximately 1,000 Ω·μm² and approximately 50,000 Ω·μm²; this typically corresponds with a tunnel barrier thickness (e.g. an MgO tunnel barrier thickness) of between approximately 1.5 nm and approximately 2.5 nm. In many embodiments, the implemented MEJs are characterized in that the respective voltage controlled interfacial effect can generate effective fields as large as 600 Oe per volt. This notion can also be understood by considering characteristic “VCMA coefficient” values of MEJs relative to MTJs. Conventional MTJs are typically characterized by VCMA coefficient values of less than approximately 30 fJ/V·m; by contrast, MEJs can be characterized by VCMA coefficient values of greater than approximately 80 fJ/V·m. In many embodiments, MEJs can be characterized by VCMA coefficient values of greater than approximately 250 fJ/V·m. As can be appreciated, VCMA coefficient values can be determined using any of a variety of standard measurement techniques. As can further be appreciated, the particular MEJ characteristics that are achieved are a function of the particular materials implemented, and the manner in which they are implemented. Additionally, as can be appreciated, any suitable MEJ can be implemented that sufficiently harnesses VCMA phenomena in accordance with embodiments of the invention. Embodiments of the invention are not limited to particular MEJ configurations.

Notably, the magnetization direction, and the related characteristics of magnetic anisotropy, can be established for the FM fixed and FM free layers using any suitable method. For instance, the shapes of the constituent FM fixed layer, FM free layer, and dielectric layer, can be selected based on desired magnetization direction orientations. For example, implementing FM fixed, FM free, and dielectric layers that have an elongated shape, e.g. have an elliptical cross-section, may tend to induce magnetic anisotropy that is in the direction of the length of the elongated axis—i.e. the FM fixed and FM free layers will possess a tendency to adopt a direction of magnetization along the length of the elongated axis. In other words, the direction of the magnetization is ‘in-plane’. Alternatively, where it is desired that the magnetic anisotropy has a directional component that is perpendicular to the FM fixed and FM free layers (i.e., ‘out-of-plane’), the shape of the layers can be made to be symmetrical, e.g. circular, and further the FM layers can be made to be thin. In this case, while the tendency of the magnetization to remain in-plane may still exist, it may not have a preferred directionality within the plane of the layer. Because the FM layers are relatively thinner, the anisotropic effects that result from interfaces between the FM layers and any adjacent layers, which tend to be out-of-plane, may tend to dominate the overall anisotropy of the FM layer. Alternatively, a material may be used for the FM fixed or free layers which has a bulk perpendicular anisotropy, i.e. an anisotropy originating from its bulk (volume) rather than from its interfaces with other adjacent layers. The FM free or fixed layers may also consist of a number of sub-layers, with the interfacial anisotropy between individual sub-layers giving rise to an effective bulk anisotropy to the material as a whole. Additionally, FM free or fixed layers may be constructed which combine these effects, and for example have both interfacial and bulk contributions to perpendicular anisotropy. Of course, any suitable methods for imposing magnetic anisotropy can be implemented in accordance with many embodiments of the invention.

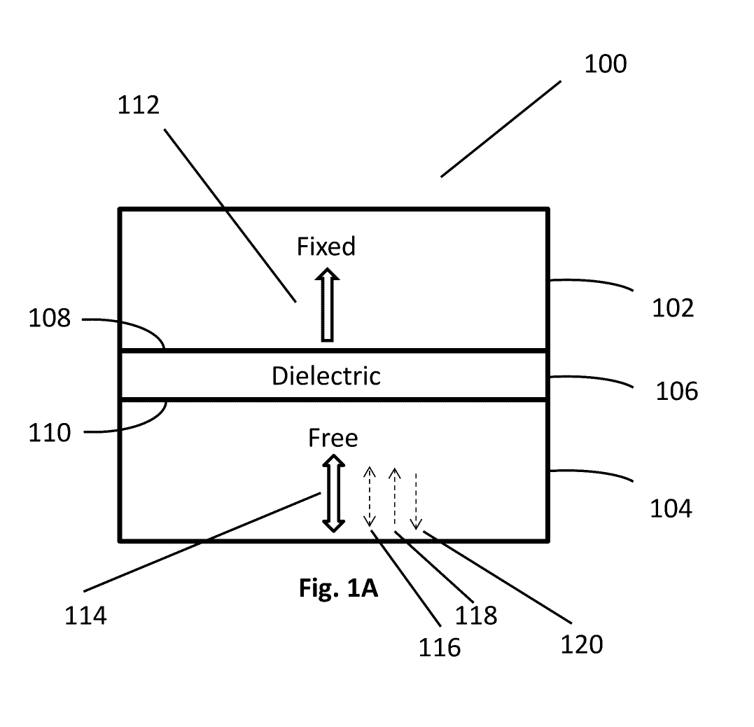

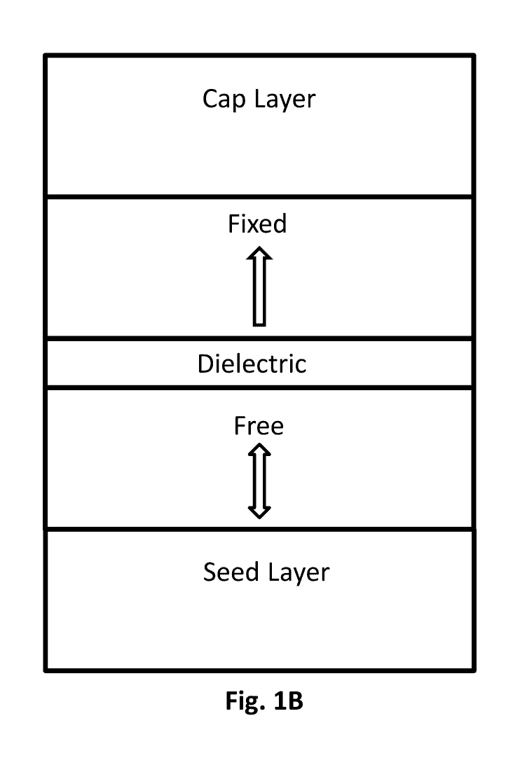

FIG. 1A illustrates an MEJ whereby the FM fixed layer and the FM free layer are separated by, and directly adjoined to, a dielectric layer. In particular, in the illustration, the MEJ 100 includes an FM fixed layer 102 that is adjoined to a dielectric layer 106, thereby forming a first interface 108; the MEJ further includes an FM free layer 104 that is adjoined to the dielectric layer 106 on an opposing side of the first interface 108, and thereby forms a second interface 110. The MEJ 100 has an FM fixed layer 102 that has a magnetization direction 112 that is out-of-plane (i.e. it is characterized by perpendicular magnetic anisotropy), and depicted in the illustration as pointing upward. Accordingly, the FM free layer is configured such that it can adopt a magnetization direction 114 that is either parallel with or antiparallel with the magnetization direction of the FM fixed layer. For reference, the easy axis 116 is illustrated, as well as a parallel magnetization direction 118, and an antiparallel magnetization direction 120. Additional contacts (capping or seed materials, or multilayers of materials, not shown in FIG. 1A) may be attached to the FM free layer 104 and the FM fixed layer 102, thereby forming additional interfaces. Thus, for example, FIG. 1B illustrates an MEJ and depicts its constituent cap/seed layers. The contacts can both contribute to the electrical and magnetic characteristics of the device by providing additional interfaces, and can also be used to apply a potential difference across the device. Additionally, it should of course be understood that MEJs can include metallic contacts that can allow them to interconnect with other electrical components.

By appropriately selecting the materials, the MEJ can be configured such that the application of a potential difference across the FM fixed layer and the FM free layer can modify the magnetic anisotropy of the FM free layer. For example, whereas in FIGS. 1A-1B, the magnetization direction of the FM free layer is depicted as being out-of-plane, the application of a voltage may distort the magnetization direction of the FM free layer such that it includes a component that is at least partially in-plane. This ‘voltage-controlled magnetic anisotropy’ (VCMA) phenomena can be used to facilitate the switching (defining) of the magnetization direction of the free layer. The particular dynamics of the modification of the magnetic anisotropy will be discussed below in the section entitled “MEJ Operating Principles.” Suitable materials for the FM layers such that this effect can be implemented include iron, nickel, manganese, cobalt, FeCoB, FeGaB, FePd, FePt; further, any compounds or alloys that include these materials may also be suitable. Suitable materials for the dielectric layer include MgO and Al₂O₃. Suitable materials for the seed/capping layers may include: Molybdenum, Tungsten, Iridium, Bismuth, Rhenium, Gold, and combinations thereof. Of course, it should be understood that the material selection is not limited to those recited—any suitable FM material can be used for the FM fixed and free layers, any suitable material can be used for the dielectric layer, and any suitable materials can be used for the seed/capping layers. It should also be understood that each of the FM free layer, FM fixed layer, dielectric layer, and seed/capping layers may consist of a number of sub-layers, which acting together provide the functionality of the respective layer.

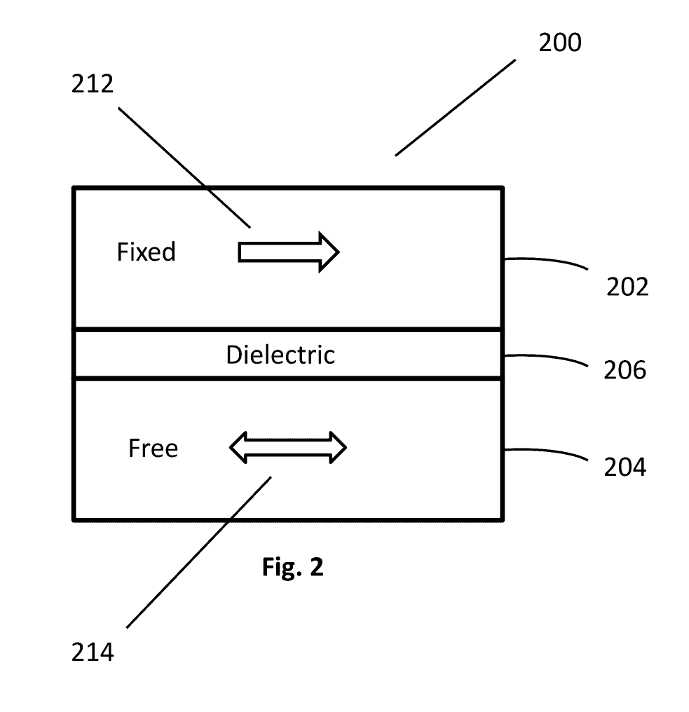

FIG. 2 illustrates an MEJ whereby the orientation of the magnetization direction is ‘in-plane.’ In particular, the MEJ 200 is similarly configured to that seen in FIG. 1, with an FM fixed layer 202 and an FM free layer 204 adjoined to a dielectric layer 206. However, unlike the MEJ in FIG. 1, the magnetization directions of the FM fixed and FM free layers, 212 and 214 respectively, are ‘in-plane.’ As before, additional contacts (capping or seed materials, or multilayers of materials, not shown) may be attached to the FM free layer 204 and the FM fixed layer 202, thereby forming additional interfaces. The contacts both contribute to the electrical and magnetic characteristics of the device by providing additional interfaces, and can also be used to apply a potential difference across the device. It should also be understood that each of the FM free layer, FM fixed layer, and dielectric layer may consist of a number of sub-layers, which acting together provide the functionality of the respective layer.

Of course, it should be understood that the direction of magnetization for the FM layers can be in any direction, as long as the FM free layer can adopt a direction of magnetization that is either substantially parallel with or antiparallel with the direction of magnetization of the FM fixed layer. For example, the direction of magnetization can include both in-plane and out-of-plane components.

In many instances, an MEJ includes additional adjunct layers that function to facilitate the operation of the MEJ. For example, in many instances, the FM free layer includes a capping or seed layer, which can (1) help induce greater electron spin perpendicular to the surface of the layer, thereby increasing its perpendicular magnetic anisotropy, and/or (2) can further enhance the sensitivity to the application of an electrical potential difference. In general, the seed/cap layers can beneficially promote the crystallinity of the ferromagnetic layers. The seed layer can also serve to separate a corresponding ferromagnetic layer from an ‘underlayer.’ As discussed in the '888 patent application, the capping/seed layers can include one of: Hf, Mo, W, Ir, Bi, Re, and/or Au; the listed elements can be incorporated by themselves, in combination with one another, or in combination with more conventional materials, such as Ta, Ru, Pt, Pd.

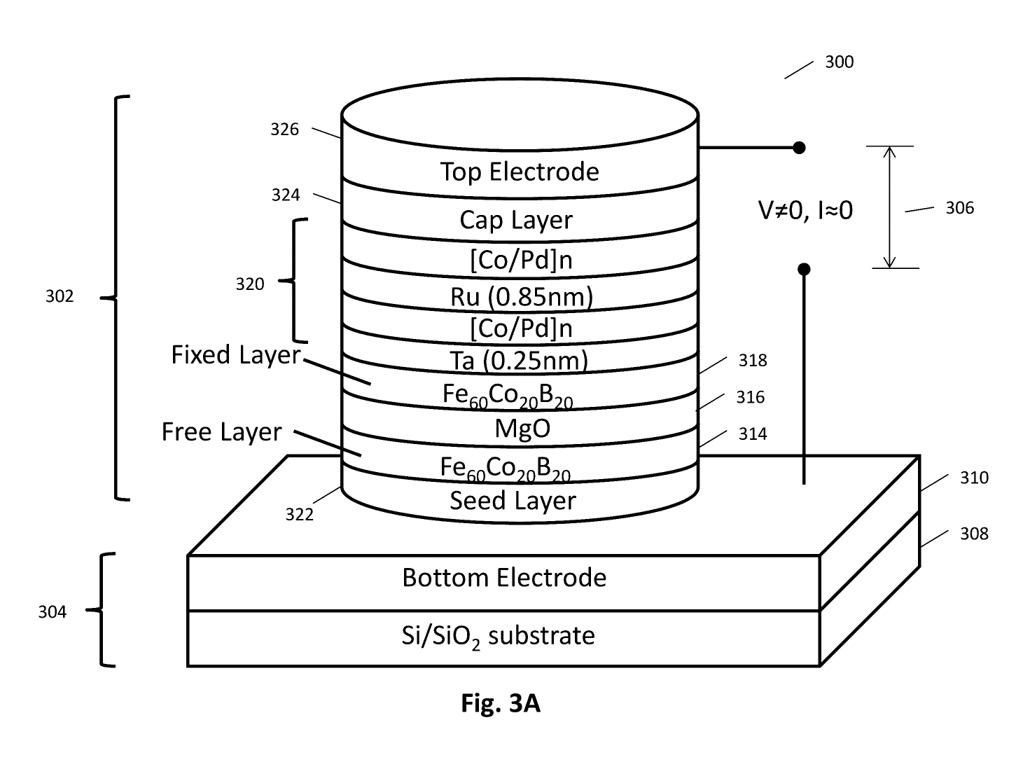

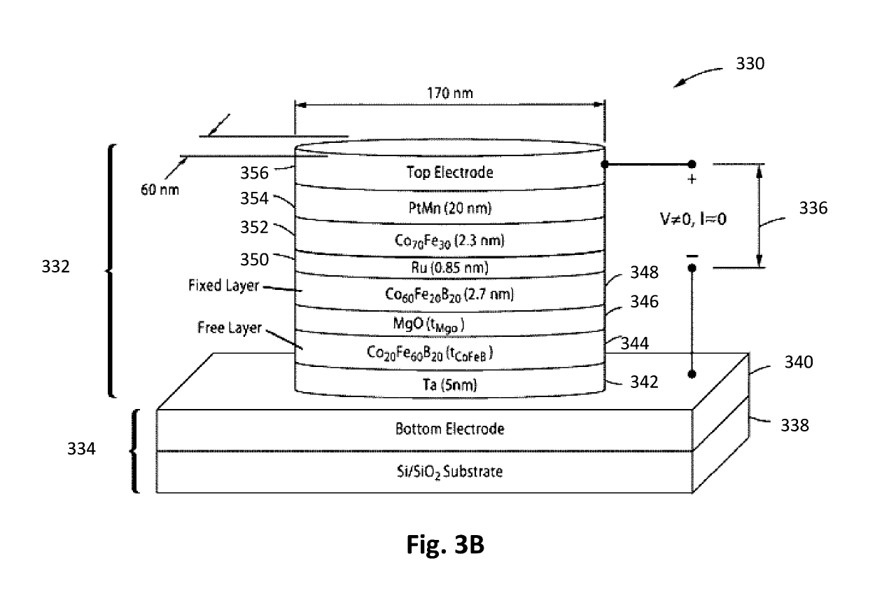

FIG. 3A illustrates an MEJ 300, including suitable materials, characterized by out-of-plane magnetization direction of the magnetic free, fixed and pinning layers that can be implemented in accordance with certain embodiments of the invention. In particular, it is depicted that a pillar section 302 extends from a planar section 304. A voltage is shown being applied 306 between the top and bottom of the pillar. By way of example, an Si/SiO₂ substrate 308 is seen over which is a bottom electrode 310. In particular, the fixed 318 and free layers 314 comprise a FeCoB alloy, and are separated by an MgO dielectric layer 316. The free layer 314 can have a thickness ranging from, but not limited to, approximately 0.8 nm to approximately 1.6 nm. The fixed layer 318 can have a thickness of approximately, but not limited to, 0.8 nm to 1.6 nm. The dielectric layer 316 can have a thickness ranging from, but not limited to, approximately 0.8 nm to 2.5 nm. The configuration is further depicted as including an aggregate of layers comprising one of: Co/Pd, Ru, and Ta; the aggregate of layers 320 can enhance the viability of the MEJ configuration. For example, the layers comprising Co/Pd can act as ‘pinning layers’ that better establish the perpendicular magnetic anisotropy of the fixed layer, and the layer comprising Ta can act to better adhere the pinning layers to the fixed layer via interlayer exchange coupling. Each of the constituent layers can be realized with any suitable thickness in accordance with embodiments of the invention. For instance, the layer including Ruthenium can have a thickness of approximately 0.85 nm. The configuration is further depicted as including cap 324 and seed 322 layers, including top 326 and bottom electrodes 310, and being disposed on a Si/SiO₂ substrate 308. Notably, the layers are depicted as having a circular (symmetric) cross-section; this geometry can help facilitate perpendicular magnetic anisotropy. While a particular configuration is depicted in FIG. 3A, it should be clear that any suitable MEJ can be implemented in accordance with embodiments of the invention.

FIG. 3B illustrates another MEJ 330 configuration that includes multiple layers that work in aggregate to facilitate the functionality of the MEJ 330. More specifically, the MEJ 330 depicted in FIG. 3B is characterized by in-plane magnetization direction of the magnetic free, fixed and pinning layers. A pillar section 332 extends from a planar section 334. A voltage is shown being applied 336 between the top and bottom of the pillar. By way of example, an Si/SiO₂ substrate 338 is seen over which is a bottom electrode 340. The pillar 332 comprises the following layers in order: Ta 342 (e.g., 5 nm in thickness); a free layer 344 comprising an Fe-rich CoFeB material (e.g. Co₂₀Fe₆₀B₂₀ having a thickness generally ranging from, but not limited to, 0.8 nm-1.6 nm); a dielectric layer 346 comprising a dielectric oxide such as MgO or Al₂O₃ having a thickness of approximately, but not limited to, 0.8-1.4 nm); a FM fixed layer 348 comprising a CoFeB material (e.g. Co₆₀Fe₂₀B₂₀ having a thickness of approximately, but not limited to, 2.7 nm); a metal layer (e.g. Ru 350 having a thickness of approximately, but not limited to, 0.85 nm) to provide antiferromagnetic inter-layer exchange coupling; an exchange-biased layer 352 of Co₇₀Fe₃₀ (e.g., thickness of approximately, but not limited to, 2.3 nm), the magnetization orientation of which is pinned by exchange bias using an anti-ferromagnetic layer 354, e.g. PtMn, IrMn, or a like material having a thickness of approximately, but not limited to, 20 nm); and a top electrode 356. By way of example and not limitation, the pillar of the device depicted is in the shape of a 170 nm×60 nm elliptical nanopillar. In this illustration, Ta layer 342 is used as a seed layer to help induce a larger electron spin polarization and/or enhance the electric-field sensitivity of magnetic properties (such as anisotropy) in the FM free layer. It also acts as a sink of B atoms during annealing of the material stack after deposition, resulting in better crystallization of the FM free layer and thereby increasing the TMR and/or VCMA effect. Of course any suitable materials can be used as a capping or seed layer 342; for example, as mentioned above, in many embodiments of the invention, the seed and/or cap layers include one of: Molybdenum, Tungsten, Hafnium, Iridium, Bismuth, Rhenium, and/or Gold. More generally, any suitable adjunct layers that can help facilitate the proper functioning of the MEJ can be implemented in an MEJ that can be implemented in accordance with certain embodiments of the invention.

MEJs can also include a semi-fixed layer which has a magnetic anisotropy that is altered by the application of a potential difference. In many instances the characteristic magnetic anisotropy of the semi-fixed layer is a function of the applied voltage. For example in many cases, the direction of the magnetization of the semi-fixed layer is oriented in the plane of the layer in the absence of a potential difference across the MEJ. However, when a potential difference is applied, the magnetic anisotropy is altered such that the magnetization includes a strengthened out-of-plane component. Moreover, the extent to which the magnetic anisotropy of the semi-fixed layer is modified as a function of applied voltage can be made to be less than the extent to which the magnetic anisotropy of the FM free layer is modified as a function of applied voltage. The incorporation of a semi-fixed layer can facilitate a more nuanced operation of the MEJ (to be discussed below in the section entitled “MEJ Operating Principles”).

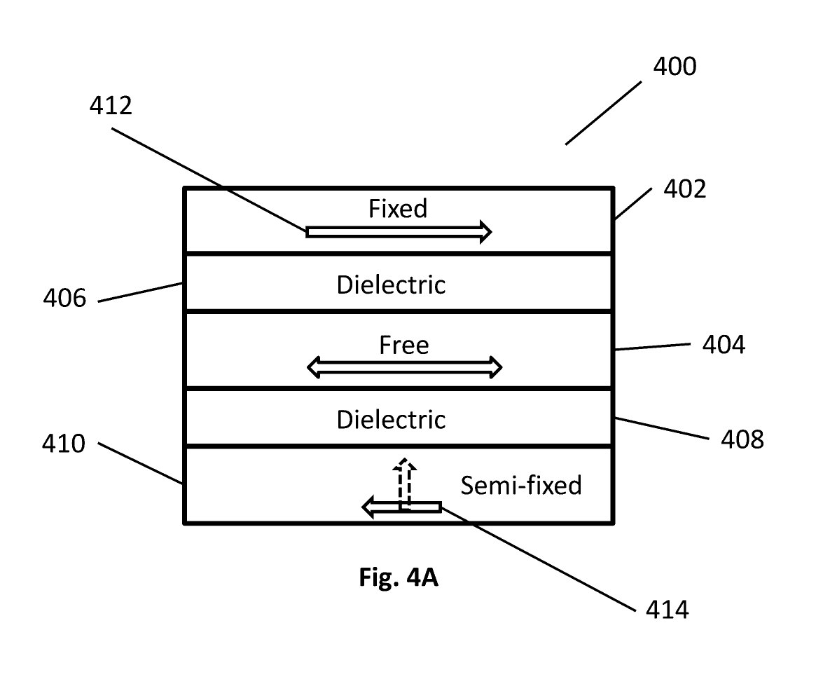

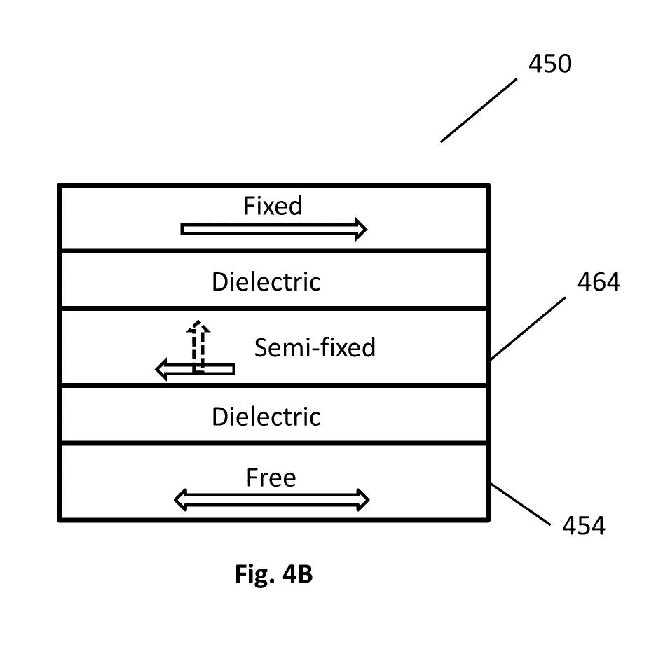

FIG. 4A illustrates an MEJ that includes a semi-fixed layer. In particular, the configuration of the MEJ 400 is similar to that depicted in FIG. 1, insofar as it includes an FM fixed layer 402 and an FM free layer 404 separated by a dielectric layer 406. However, the MEJ 400 further includes a second dielectric layer 408 adjoined to the FM free layer 404 such that the FM free layer is adjoined to two dielectric layers, 406 and 408 respectively, on opposing sides. Further, a semi-fixed layer 410 is adjoined to the dielectric layer. Typically, the direction of magnetization of the semi-fixed layer 414 is antiparallel with that of the FM fixed layer 412. As mentioned above, the direction of magnetization of the semi-fixed layer can be manipulated based on the application of a voltage. In the illustration, it is depicted that the application of a potential difference adjusts the magnetic anisotropy of the semi-fixed layer such that the strength of the magnetization along a direction orthogonal to the initial direction of magnetization (in this case, out of the plane of the layer) is developed. It should of course be noted that the application of a potential difference can augment the magnetic anisotropy in any number of ways; for instance, in some MEJs, the application of a potential difference can reduce the strength of the magnetization in a direction orthogonal to the initial direction of magnetization. Note also that in the illustration, the directions of magnetization are all depicted to be in-plane where there is no potential difference. However, of course it should be understood that the direction of the magnetization can be in any suitable direction. More generally, although a particular configuration of an MEJ that includes a semi-fixed layer is depicted, it should of course be understood that a semi-fixed layer can be incorporated within an MEJ in any number of configurations. For example, FIG. 4B illustrates an MEJ that includes a semi-fixed layer that is in a different configuration than that seen in 4A. In particular, the MEJ 450 is similar to that seen in FIG. 4A, except that the positioning of the semi-fixed layer 464 and the free layer 454 is inverted. In certain situations, such a configuration may be more desirable.

The generally understood principles of the operation of MEJs are now discussed.

### General Principles of MEJ Operation

MEJ operating principles—as they are currently understood—are now discussed. Note that embodiments of the invention are not constrained to the particular realization of these phenomena. Rather, the presumed underlying physical phenomena are being presented to inform the reader as to how MEJs are believed to operate. MEJs generally function to achieve two distinct states using the principles of magnetoresistance. As mentioned above, magnetoresistance principles regard how the resistance of a thin film structure that includes alternating layers of ferromagnetic and non-magnetic layers depends upon whether the ferromagnetic layers are in a substantially parallel or antiparallel alignment. Thus, an MEJ can achieve a first state where its FM layers have magnetization directions that are substantially parallel, and a second state where its FM layers have magnetization directions that are substantially antiparallel. MEJs further rely on voltage-controlled magnetic anisotropy (VCMA) phenomena. Generally, VCMA phenomena regard how the application of a voltage to a ferromagnetic material that is adjoined to an adjacent dielectric layer can impact the characteristics of the ferromagnetic material's magnetic anisotropy. For example, it has been demonstrated that the interface of oxides such as MgO with metallic ferromagnets such as Fe, CoFe, and CoFeB can exhibit a large perpendicular magnetic anisotropy which is furthermore sensitive to voltages applied across the dielectric layer, an effect that has been attributed to spin-dependent charge screening, hybridization of atomic orbitals at the interface, and to the electric field induced modulation of the relative occupancy of atomic orbitals at the interface. MEJs can exploit this phenomenon to achieve two distinct states. For example, MEJs can employ one of two mechanisms to achieve different states: first, MEJs can be configured such that the application of a potential difference across the MEJ functions to reduce the coercivity of the FM free layer, such that it can be subject to magnetization in a desired direction, e.g. either substantially parallel with or antiparallel with the magnetization direction of the fixed layer; second, MEJ operation can rely on precessional switching (or resonant switching), whereby by precisely subjecting the MEJ to voltage pulses of precise duration, the direction of magnetization of the FM free layer can be made to switch.

In many instances, MEJ operation is based on reducing the coercivity of the FM free layer such that it can adopt a desired magnetization direction. With a reduced coercivity, the FM free layer can adopt a magnetization direction in any suitable way. For instance, the magnetization can result from: an externally applied magnetic field, the magnetic field of the FM fixed layer; the application of a spin-transfer torque (STT) current; the magnetic field of a FM semi-fixed layer; the application of a current in an adjacent metal line inducing a spin-orbit torque (SOT); and any combination of these mechanisms, or any other suitable method of magnetizing the FM free layer with a reduced coercivity.

By way of example and not limitation, examples of suitable ranges for the applied magnetic field are in the range of 0 to 100 Oe. The magnitude of the electric field applied across the device to reduce its coercivity or bring about resonant switching can be approximately in the range of 0.1-2.0 V/nm, with lower electric fields required for materials combinations that exhibit a larger VCMA effect. The magnitude of the STT current used to assist the switching may be in the range of approximately 0.1-1.0 MA/cm².

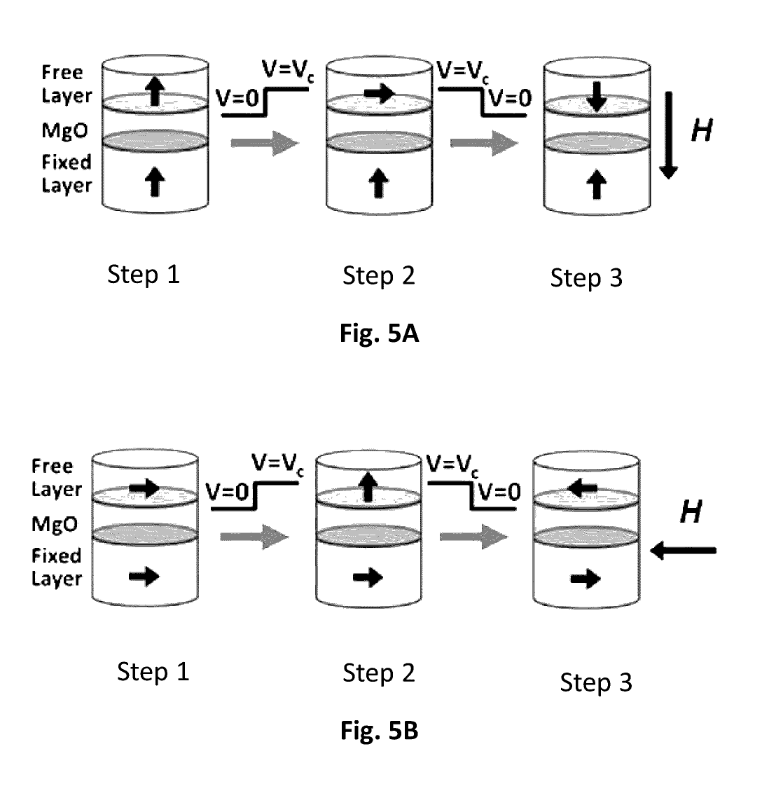

FIG. 5A depicts how the application of a potential difference can reduce the coercivity of the free layer such that an externally applied magnetic field H can impose a magnetization switching on the free layer. In the illustration, in step 1, the FM free layer and the FM fixed layer have a magnetization direction that is substantially out-of-plane; the FM free layer has a magnetization direction that is parallel with that of the FM fixed layer. Further, in Step 1, the coercivity of the FM free layer is such that the FM free layer is not prone to having its magnetization direction reversed by the magnetic field H, which is in a direction antiparallel with the magnetization direction of the FM fixed layer. However, a Voltage, V, is then applied, which results in step 2, where the voltage V, has magnified the orthogonal magnetization direction component of the free layer (in-plane) relative to the out-of-plane direction component. Correspondingly, the coercivity of the free layer is reduced such that such that it is subject to magnetization by an out-of-plane magnetic field H. Accordingly, when the potential difference V, is removed, VCMA effects are removed and the magnetic field H, which is substantially anti-parallel to the magnetization direction of the FM fixed layer, causes the FM free layer to adopt a direction of magnetization that is antiparallel with the magnetization direction of the FM fixed layer. Hence, as the MEJ now includes an FM fixed layer and an FM free layer that have magnetization directions that are antiparallel, it reads out a second information state (resistance value) different from the first. In general, it should be understood that in many instances where the magnetization directions of the free layer and the fixed layer are substantially out-of-plane, the application of a voltage enhances the in-plane magnetic anisotropy such that the FM free layer can be caused to adopt an in-plane magnetization direction component. Stated differently, the magnetoelectric junction is configured such that when a potential difference is applied across the magnetoelectric junction, the magnetic anisotropy of the ferromagnetic free layer is altered such that the relative strength of the magnetic anisotropy along a second easy axis that is orthogonal to the first easy axis (which corresponds to the magnetization direction of the fixed layer), or the easy plane where there is no easy axis that is orthogonal to the first easy axis, as compared to the strength of the magnetic anisotropy along the first easy axis, is magnified or reduced for the duration of the application of the potential difference. The magnetization direction can thereby be made to switch, e.g. by an external magnetic field. In general, it can be seen that by controlling the potential difference and the direction of an applied external magnetic field, an MEJ switch can be achieved.

It should of course be understood that the direction of the FM fixed layer's magnetization direction need not be out-of-plane—it can be in any suitable direction. For instance, it can be substantially in-plane. Additionally, the FM free layer can include both in-plane and out-of-plane magnetic anisotropy directional components. FIG. 5B depicts a corresponding case relative to FIG. 5A when the FM fixed and FM free layers have magnetization directions that are in-plane. It is of course important, that an FM, magnetically anisotropic, free layer be able to adopt a magnetization direction that is either substantially parallel with an FM fixed layer, or substantially antiparallel with the FM fixed layer. In other words, when unburdened by a potential difference, the FM free layer can have a direction of magnetization that is either substantially parallel with or antiparallel with the direction of the FM fixed layer's magnetization, to the extent that a distinct measurable difference in the resistance of the MEJ that results from the principles of magnetoresistance as between the two states (i.e. parallel alignment vs. antiparallel alignment) can be measured, such that two distinct information states can be defined.

Note of course that the application of an externally applied magnetic field is not the only way for the MEJ to take advantage of reduced coercivity upon application of a potential difference. For example, the magnetization of the FM fixed layer can be used to impose a magnetization direction on the free layer when the free layer has a reduced coercivity. Moreover, an MEJ can be configured to receive a spin-transfer torque (STT) current when application of a voltage causes a reduction in the coercivity of the FM free layer. Generally, STT current is a spin-polarized current that can be used to facilitate the change of magnetization direction on a ferromagnetic layer. It can originate, for example, from a current passed directly through the MEJ device, such as due to leakage when a voltage is applied, or it can be created by other means, such as by spin-orbit-torques (e.g., Rashba or Spin-Hall Effects) when a current is passed along a metal line placed adjacent to the FM free layer. Accordingly, the spin orbit torque current can then help cause the FM free layer to adopt a particular magnetization direction, where the direction of the spin orbit torque determines the direction of magnetization. This configuration is advantageous over conventional STT-RAM configurations since the reduced coercivity of the FM free layer reduces the amount of current required to cause the FM free layer to adopt a particular magnetization direction, thereby making the device more energy efficient.

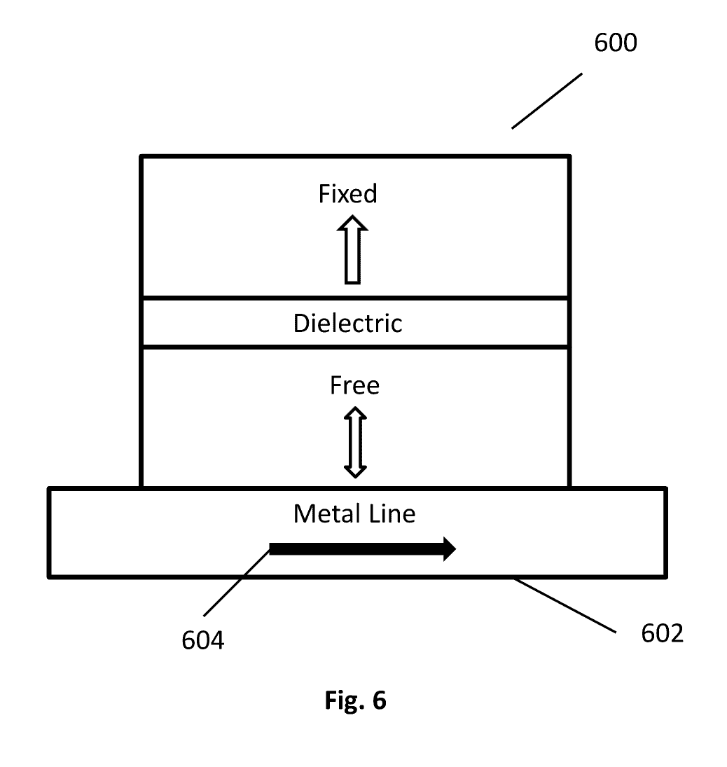

FIG. 6 depicts using a metal line disposed adjacent to an FM free layer to generate spin-orbit torques that can impose a magnetization direction change on the FM free layer. In particular, the MEJ 600 is similar to that seen in FIG. 1A, except that it further includes a metal line 602, whereby a current 604 can flow to induce spin-orbit torques, which can thereby help impose a magnetization direction change on the ferromagnetic free layer.

Additionally, in many instances, an MEJ cell can further take advantage of thermally assisted switching (TAS) principles. Generally, in accordance with TAS principles, heating up the MEJ during a writing process reduces the magnetic field required to induce switching. Thus, for instance, where STT is employed, even less current may be required to help impose a magnetization direction change on a free layer, particularly where VCMA principles have been utilized to reduce its coercivity.

Moreover, the switching of MEJs to achieve two information states can also be achieved using ‘precessional switching.’ In particular, if voltage pulses are imposed on the MEJ for a time period that is one-half of the precession of the magnetization of the free layer, then the magnetization may invert its direction. Precessional switching can offer the advantages of very high speed (down to 100 ps) and low switching energy (down to 1 fJ/bit using the VCMA effect). Using this technique, ultrafast switching times, e.g. below 1 ns, can be realized; moreover, using voltage pulses as opposed to a current, can make this technique more energetically efficient as compared to the precessional switching induced by STT currents, as is often used in STT-RAM. However, a few challenges remain in using this technique. Firstly, this technique is subject to the application of a precise pulse that is half the length of the precessional period of the magnetization layer. For instance, it has been observed that pulse durations in the range of 0.1 to 3 nanoseconds can reverse the magnetization direction. Additionally, the voltage pulse must be of suitable amplitude to cause the desired effect, e.g. reverse the direction of magnetization. Furthermore, a constant orthogonal biasing magnetic field may be necessary in order to provide a definite direction along which the FM free layer magnetization will precess. It has been determined that imposing a constant orthogonal biasing magnetic field can greatly enhance the robustness and consistency of precessional switching. Without the biasing field, due to thermal effect, the efficacy of precessional switching may be too strong a function of initial magnetization conditions and voltage pulse duration. Imposing a constant biasing magnetic field can provide a definite direction along which the magnetization of the FM free layer will precess, which can make the efficacy of precessional switching not as sensitive to initial magnetization conditions and pulse duration; thus, the consistency and robustness of precessional switching operations may be improved with an imposed biasing field.

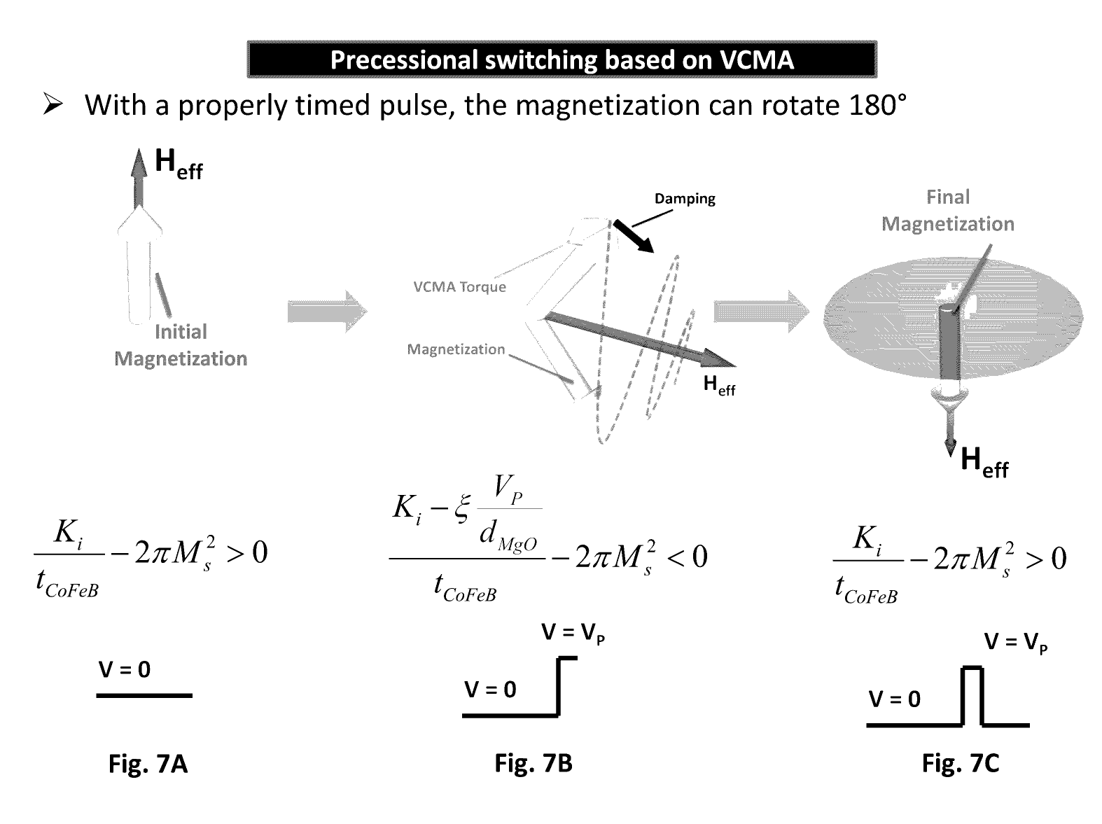

FIGS. 7A-7C illustrate the believed dynamics concerning precessional switching based on VCMA phenomena. In particular, FIG. 7A depicts an initial magnetization direction for a free layer which points upward under the influence of the total effective field H_{eff} (total energy term is positive). FIG. 7B illustrates that a voltage pulse V_{P} with proper amplitude changes the interfacial anisotropy via the VCMA effect to such an extent that the total energy becomes negative; as a result, the total effective field H_{eff} aligns in-plane, along which the free layer magnetization precesses. A properly timed pulse duration can rotate the magnetization vector by 180° as discussed above. FIG. 7C illustrates the final configuration, whereby the voltage pulse has concluded and the magnetization direction is inverted relative to the initial magnetization direction; the final magnetization direction points downward which is one of the easy axis directions of the free layer.

In any case, based on this information, it can be seen that MEJs can confer numerous advantages relative to conventional MTJs. For example, they can be controlled using voltages of a single polarity—indeed, the '739 patent, incorporated by reference above, discusses using diodes, in lieu of transistors, as access devices to the MEJ, and this configuration is enabled because MEJs can be controlled using voltage sources of a single polarity.

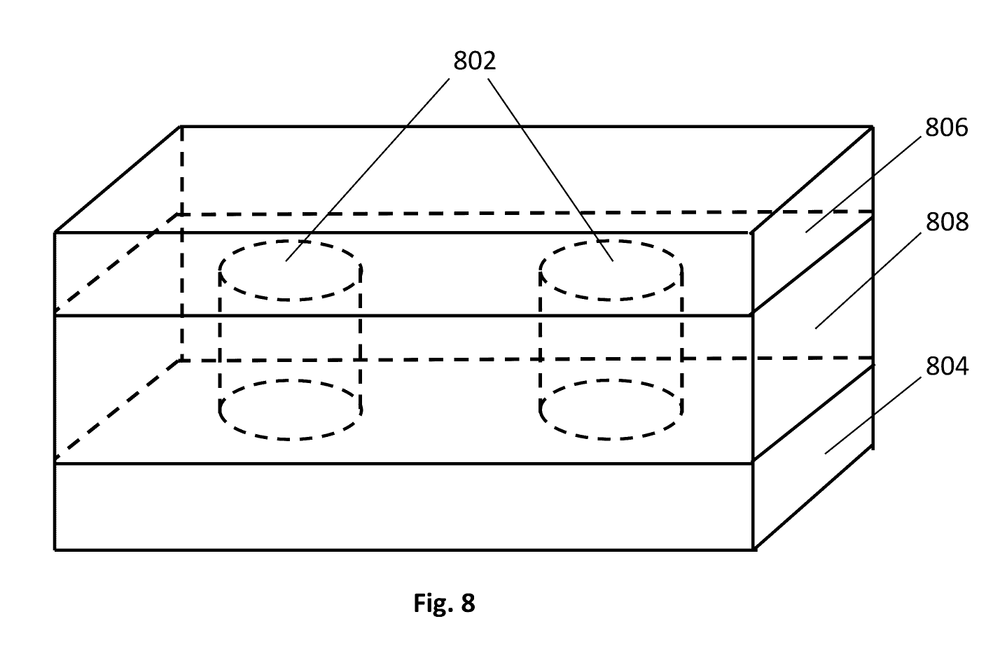

Note that while the above discussion largely regards the operation of single MEJs, it should of course be understood that in many instances, a plurality of MEJs are implemented together. For example, the '671 patent application discloses MeRAM configurations that include a plurality of MEJs disposed in a cross-bar architecture. It should be clear that MEJ systems can include a plurality of MEJs in accordance with embodiments of the invention. Where multiple MEJs are implemented, they can be separated by field insulation, and encapsulated by top and bottom layers. Thus, for example, FIG. 8 depicts the implementation of two MEJs that are housed within encapsulating layers and separated by field insulation. In particular, the MEJs 802 are encapsulated within a bottom layer 804 and a top layer 806. Field insulation 808 is implemented to isolate the MEJs and facilitate their respective operation. It should of course be appreciated that each of the top and bottom layers can include one or multiple layers of materials/structures. As can also be appreciated, the field insulation material can be any suitable material that functions to facilitate the operation of the MEJs in accordance with embodiments of the invention. While a certain configuration for the implementation of a plurality of MEJs has been illustrated and discussed, any suitable configuration that integrates a plurality of MEJs can be implemented in accordance with embodiments of the invention.

While the above discussion has largely regarded using an extrinsic magnetic field to facilitate the switching of the magnetization direction, in many embodiments of the invention, MEJs include integrated magnetization components that impose a constant magnetic field which can be used to facilitate the precessional switching of the free layer. These configurations are now discussed in greater detail below.

### MEJ Configurations Including Integrated Magnetization Components

In many embodiments of the invention, particularly effective MEJ configurations are implemented that include integrated magnetization components. For example, in many embodiments, MEJs further include a dedicated magnetization layer characterized by a fixed magnetization direction that is substantially orthogonal to the magnetization direction of the fixed layer, which thereby imposes a permanent, biasing magnetic field; the biasing magnetic field can facilitate the precessional switching of the free layer. The fixed magnetization direction of the magnetization layer can be substantially orthogonal to that of the fixed layer to the extent that robust and consistent precessional switching can be achieved. In this way, having to exclusively rely on external means for facilitating the switching of the free layer can be mitigated/avoided, and more practicable, self-reliant MEJs can be achieved.

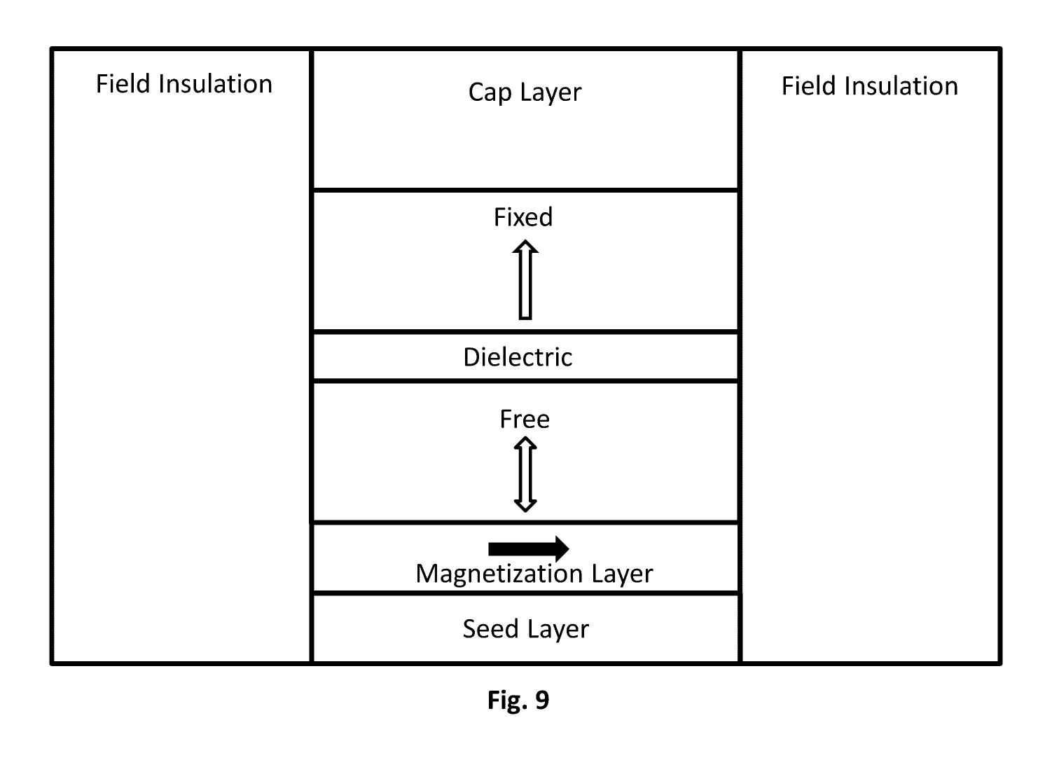

Note that magnetization components can be implemented within MEJs in any suitable way in accordance with embodiments of the invention. Thus, FIG. 9 illustrates an MEJ configuration that includes a magnetization layer disposed between the seed layer and the free layer. More particularly, it is illustrated that the magnetization layer is substantially aligned with the stack defined by the fixed layer, the dielectric layer, and the free layer. The magnetization layer is depicted as having a permanent in-plane magnetization direction, while the free layer has an easy axis that is orthogonal to the in-plane magnetization direction. Accordingly, the magnetization layer effectively imposes a permanent, biasing magnetic field that can facilitate the precessional switching of the free layer of the MEJ.

Importantly, the incorporation of the magnetization components should be highly tailored in order for them to be most effective. For example, the magnetic field imposed by the magnetization layer of FIG. 9 should be of an appropriate strength to cause the intended effect, i.e. facilitating the consistent successful precessional switching as desired. Preferably, the strength of the bias field should be at least sufficient to stabilize the free layer magnetization caused by thermal fluctuation. A stronger biasing field promotes a faster switching speed; however, it may be undesirable for the switching speed to be too fast as this circumstance can cause reliability concerns. As one example, a simple estimation gives that for 100 Oe effective field H_{eff}, the switching time (half cycle) is about 1.8 ns. In many embodiments, in order to achieve 0.1 ns to 3 ns switching time, the total bias field is in the range of 1800 Oe to 60 Oe. At the same time, the magnetic field should not be so strong that it adversely influences the magnetization directions of either the fixed layer or the free layer when there is no applied voltage to an extent that the proper operation of the MEJ is compromised.

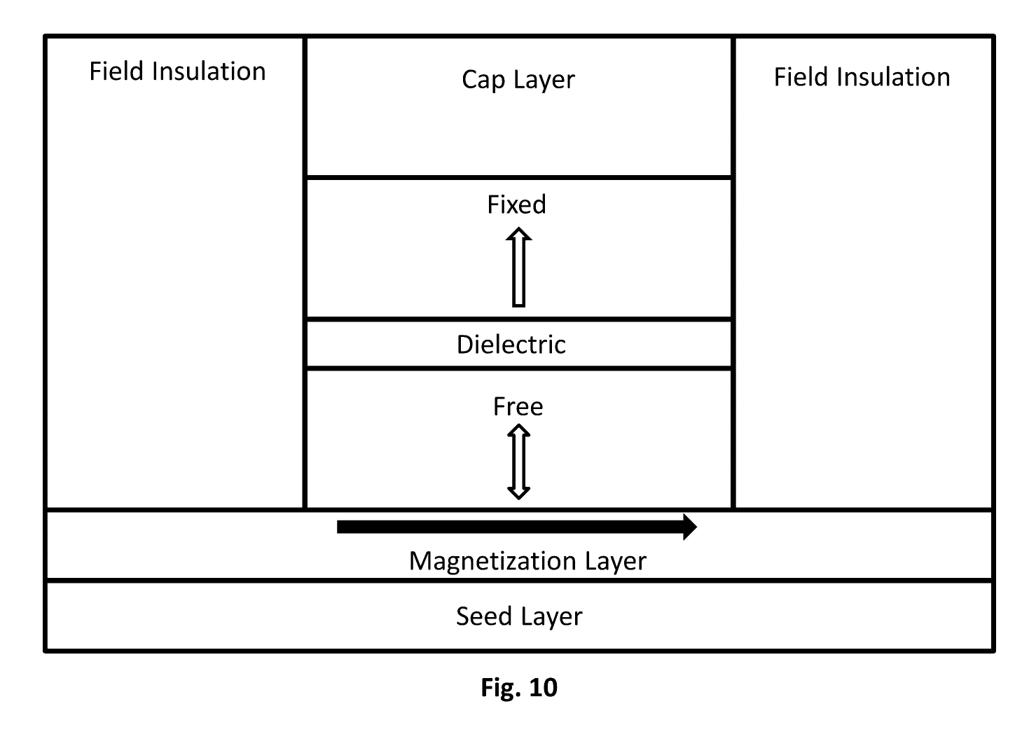

Note that the design and particular implementation of the magnetization layer can be implemented to tailor the magnetization layer to the MEJ to facilitate the proper switching of the MEJ. For instance, if a stronger magnetic field is needed for proper operation, the volume of the implemented magnetization layer can be increased. Thus, for example, FIG. 10 illustrates an MEJ including an extended magnetization layer disposed between the seed layer and the free layer. In particular, the magnetization layer is laterally extended, having a longer characteristic length relative to that seen in FIG. 9. In other words, it can be stated that the magnetization layer is defined by a planar surface extruded through a thickness, and includes portions that do not fall within a projection of the stack defined by the fixed layer, the dielectric layer, and the free layer. For clarity, the stack can be understood to have an outer surface characterized by its inclusion of the perimeters of the fixed layer, the dielectric layer, and the free layer, and the magnetization layer has portions that extend beyond the bounds of a projection of this outer surface. The larger overall volume of the magnetization layer can impose a relatively stronger magnetic field. Of course, it should be appreciated that the strength of the magnetic field required for proper operation may be a function of the particular MEJ configuration to be implemented. Accordingly, the volume of the implemented magnetization layer can be tailored accordingly.

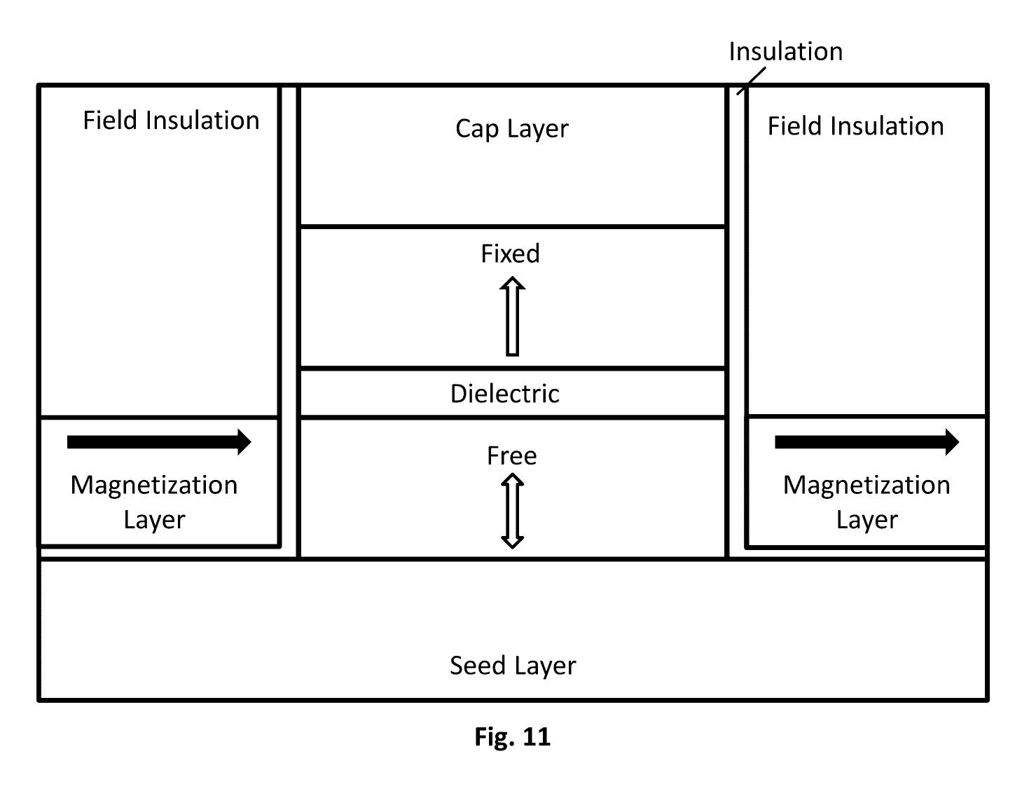

While the above description has disclosed MEJ configurations including magnetization layers disposed between the seed layer and the free layer, magnetization components can be implemented in any suitable way in accordance with embodiments of the invention. Thus, for example, FIG. 11 illustrates an MEJ configuration whereby magnetization layers are implemented that are substantially coplanar with the free layer.

FIG. 11 further depicts that additional insulation is used to separate the hard magnetic materials from the free layer.

It should be noted that although FIGS. 9, 10, and 11 depict a certain ordering of the stack including the seed layer, the free layer, the magnetization layer, the dielectric layer, the fixed layer and the cap layer, any suitable ordering for the stack can be implemented. Thus, for instance, in many embodiments, MEJ configurations are implemented whereby the free layer is proximate the cap layer (as opposed to being proximate the free layer); correspondingly, in many embodiments, the magnetization layer is disposed in between the cap layer and the free layer. In general, MEJ configurations including magnetization layers can be arranged in any suitable way in accordance with embodiments of the invention.

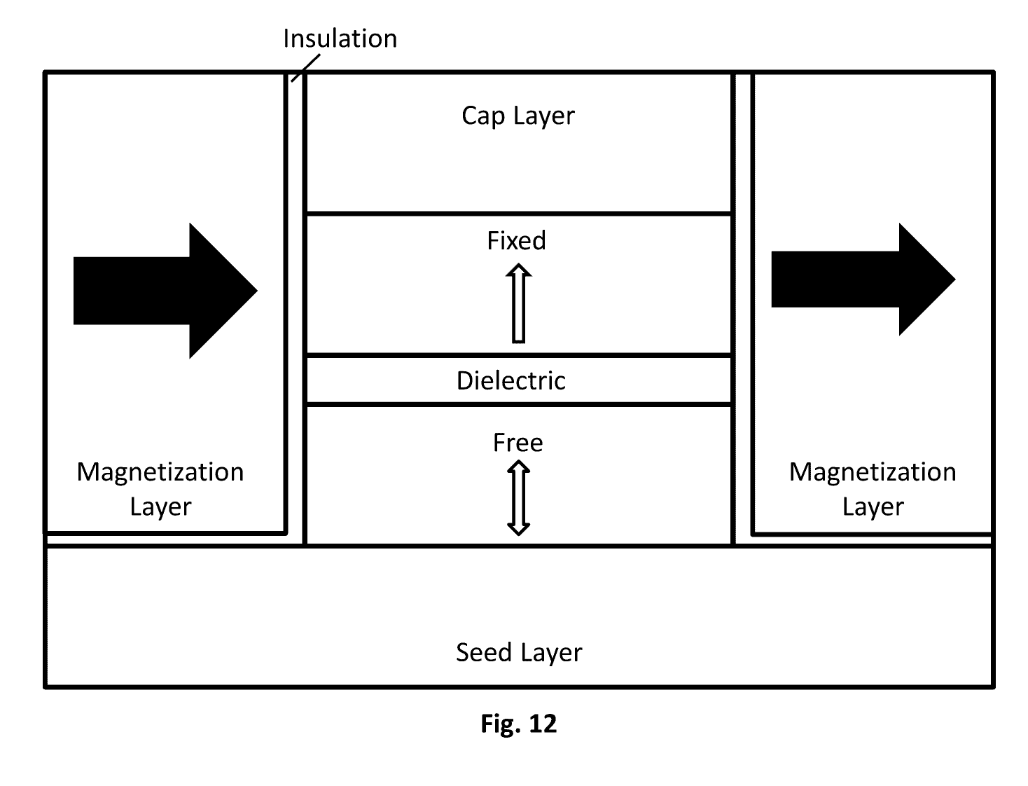

While FIG. 11 depicts magnetization layers that are coplanar with the free layer, recall that the volume of the magnetization layers can be adjusted in accordance with embodiments of the invention, e.g. to tailor imposed magnetic field accordingly. Thus, FIG. 12 illustrates an MEJ configuration including magnetization layers that are substantially coplanar with the stack including the free layer, the dielectric layer, the fixed layer, and the cap layer; insulation is used to separate the hard magnetic materials from the stack. And as discussed previously, the greater volume of the magnetization layer can correspond with the imposition of a greater magnetic field, which can facilitate the switching of the free layer. As can be appreciated, the volume of any implemented magnetization layers can be tailored to correspond with the magnetic field that is required in order to facilitate the proper functioning of the MEJ. Thus, the magnetization layer(s) can conform to any suitable volume in accordance with many embodiments of the invention.

Note that FIGS. 11 and 12 can also be said to be characterized in that the magnetization layers are depicted as not falling within a projection of the outer surface of the stack defined by the fixed layer, the dielectric layer, and the free layer. Of course, while certain geometric relationships have been illustrated, the fixed layer, the free layer, the dielectric layer, and the magnetization layer can be implemented in any of a variety of suitable arrangements in accordance with many embodiments of the invention. Embodiments of the invention are not limited to the depicted configurations.

Note that the magnetization layers discussed above can be fabricated from any suitable materials. For instance, in many embodiments, the magnetization layers comprise one of: CoPt, CoPtCr, and combinations thereof. To be clear, any suitable materials can be used to implement the above-described magnetization layers.

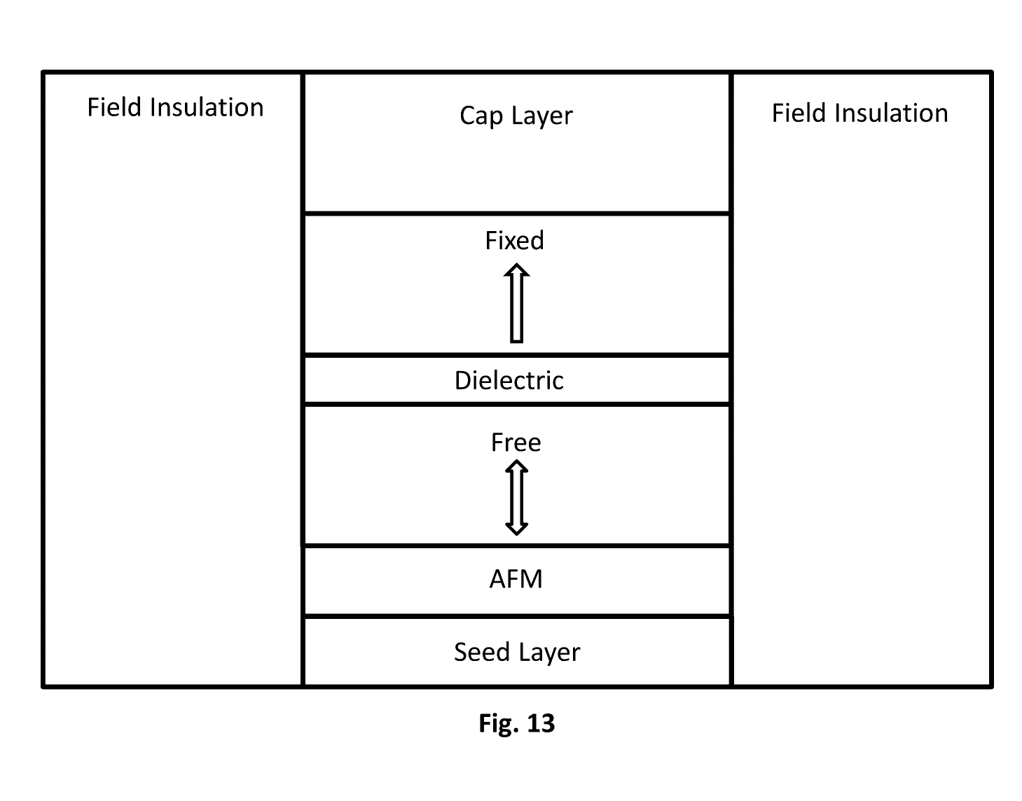

In many embodiments of the invention, MEJ configurations include antiferromagnetic layers. The interaction between antiferromagnetic layer and the free layer (e.g. the exchange bias) can result in an orthogonal magnetic field which can facilitate precessional switching as described above. Thus, for example, FIG. 13 illustrates the incorporation of an antiferromagnetic layer within an MEJ in accordance with embodiments of the invention. In particular, the configuration is similar to that seen in FIG. 9, except that the MEJ includes an antiferromagnetic layer in place of the more direct magnetization layer. Of course, as can be appreciated, antiferromagnetic layers can be implemented in any suitable way that can result in the integration of a constant biasing magnetic field in accordance with embodiments of the invention. For instance, while FIG. 13 depicts the free layer and the antiferromagnetic layer disposed proximate the seed layer at the “bottom” of the MEJ, in many embodiments, the free layer and the antiferromagnetic layer are disposed proximate the cap layer towards the “top” of the MEJ. In other words, the integration of an antiferromagnetic layer in an MEJ is not limited to the configuration seen in FIG. 13.

While the above-depicted configurations largely regard MEJs having fixed and free layers characterized by perpendicular magnetic anisotropy, in many embodiments MEJ configurations having fixed and free layers characterized by in-plane magnetic anisotropy are implemented in conjunction with a magnetization component layer that is characterized by an out-of-plane magnetization direction. In these configurations, the applied voltage pulse needs to increase the perpendicular magnetic anisotropy in order to overcome the demagnetization for the free layer to precess; this may require a large VCMA coefficient.

As can be appreciated, the above-described structures can be fabricated using any of a variety of standard deposition techniques in accordance with embodiments of the invention. For example, in many instances, sputtering techniques are used to deposit the constituent layers. For instance, the MEJ manufacturing techniques described in the '739 patent, incorporated by reference above, can be used. The '739 patent is reincorporated by reference herein, especially as it pertains to the fabrication of MEJs.

Thus, an MEJ can be prepared by depositing continuous multiple layers of films of different material (e.g. CoFeB, MgO, PtMn, IrMn, synthetic anti-ferromagnetic material). For example, the films for the fixed ferromagnetic layers and free ferromagnetic layers can be deposited by a physical vapor deposition (PVD) system and subsequently annealed in an in-plane or out-of-plane magnetic field, or without a magnetic field, above 200° C. Annealing may take place under vacuum conditions to avoid oxidation of the material stack. As a further example, metallic films can be deposited by DC frequency sputtering while the dielectric layer is deposited by radio-frequency sputtering from a ceramic MgO target, or by DC sputtering of Mg and subsequent oxidation, or by a combination of both. The film deposition can be performed by deposition uniformly on a surface that is held at approximately ambient or elevated temperatures. The surfaces of these various layers may be planarized after each layer is formed to achieve better smoothness, and the planarization techniques include chemical-mechanical polishing. The deposited stacks may also be heat treated to improve the surface smoothness. The thickness of each layer can be in the range of 0.1 to 10 nm, and is designed to achieve certain spin polarization or magnetization, resistivity, voltage ranges to flip the spin, and various other electrical performance parameters. For example, the dielectric tunnel layer is designed to be thick enough to make the current-induced spin-transfer torque small. The switching speeds in MEJs are adjusted based on their design and composition. As to the shape of the MEJ devices, depending on the material, the in-plane configuration tends to perform better if the flat end surface were elliptical, oblong, rectangular, etc., so that the geometry is elongated in one direction (length is greater than width). In some instances, the MEJs can be made to have a circular geometry. In general, any suitable deposition techniques may be used to implement the above-described structures. More generally, any suitable manufacturing techniques can be used to implement the above-described structures.

In general, while certain features of the systems and methods have been illustrated and described herein, modifications, substitutions, changes and equivalents will occur to those skilled in the art. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described. For example, the MEJs discussed may be modified, but still consistent with the principles described herein.

What is claimed is:

1. A magnetoelectric junction comprising:
a first ferromagnetic fixed layer;
a ferromagnetic free layer that is magnetically anisotropic;
a dielectric layer that is disposed between the first ferromagnetic fixed layer and the ferromagnetic free layer;
wherein:
each of the ferromagnetic fixed layer, the ferromagnetic free layer, and the dielectric layer are characterized by a planar surface extruded through a thickness; and
the ferromagnetic free layer, the dielectric layer, and the ferromagnetic fixed layer define a stack with an outer surface characterized by its inclusion of the perimeters of said planar surfaces;
at least one magnetization layer that is disposed proximate the ferromagnetic free layer;
wherein:
the first ferromagnetic fixed layer is magnetized in a first direction;
the ferromagnetic free layer can adopt a magnetization direction that is either substantially parallel with or substantially antiparallel with the first direction;
the at least one magnetization layer is magnetized in a second direction that is orthogonal to the first direction;
the magnetoelectric junction is characterized by a VCMA coefficient of at least approximately 80 fJ/V·m; and
the magnetoelectric junction is configured such that a voltage pulse of a proper length in time can cause the ferromagnetic free layer to invert its magnetization direction.

2. The magnetoelectric junction of claim 1, wherein the ferromagnetic free layer is characterized by perpendicular magnetic anisotropy, and the at least one magnetization layer is characterized by in-plane magnetic anisotropy.

3. The magnetoelectric junction of claim 2 wherein the at least one magnetization layer defines a magnetic field that is of sufficient strength to facilitate the precessional switching of the free layer when the voltage pulse of the proper length in time is applied.

4. The magnetoelectric junction of claim 3, wherein the at least one magnetization layer is configured to impose a magnetic field having a strength of between approximately 60 Oe and approximately 1800 Oe.

5. The magnetoelectric junction of claim 4, wherein the at least one magnetization layer is disposed within a projection of the outer surface of the stack, such that the at least one magnetization layer is aligned with the stack.

6. The magnetoelectric junction of claim 4, wherein only a portion of the at least one magnetization layer is disposed within a projection of the outer surface of the stack.

7. The magnetoelectric junction of claim 4, wherein the at least one magnetization layer disposed entirely outside of a projection of the outer surface of the stack.

8. The magnetoelectric junction of claim 7, wherein the magnetization layer is substantially coplanar with the stack.

9. The magnetoelectric junction of claim 4, wherein the magnetization layer comprises one of: CoPt, CoPtCr, and combinations thereof.

10. The magnetoelectric junction of claim 4 further comprising field insulation.

11. The magnetoelectric junction of claim 4 further comprising a cap layer and a seed layer.

12. The magnetoelectric junction of claim 11, wherein at least one of the seed layer and the cap layer comprises one of: Molybdenum, Tungsten, Iridium, Bismuth, Rhenium, and Gold.

13. The magnetoelectric junction of claim 4, wherein at least one of the ferromagnetic fixed layer and the ferromagnetic free layer comprises one of: iron, nickel, manganese, cobalt, FeCoB, FeGaB, FePd, FePt, and combinations thereof.

14. The magnetoelectric junction of claim 4, wherein the dielectric layer comprises one of: MgO and Al₂O₃.

15. The magnetoelectric junction of claim 4, wherein the magnetoelectric junction is characterized by a VCMA coefficient of at least approximately 250 fJ/V·m.

16. A magnetoelectric junction comprising:
a first ferromagnetic fixed layer;
a ferromagnetic free layer that is magnetically anisotropic;
a dielectric layer that is disposed between the first ferromagnetic fixed layer and the ferromagnetic free layer;
an antiferromagnetic layer that is disposed adjacently to the ferromagnetic free layer;
wherein:
the first ferromagnetic fixed layer is magnetized in a first direction;
the ferromagnetic free layer can adopt a magnetization direction that is either substantially parallel with or substantially antiparallel with the first direction;
the magnetoelectric junction is characterized by a VCMA coefficient of at least approximately 80 fJ/V·m; and
the magnetoelectric junction is configured such that a voltage pulse of a proper length in time can cause the ferromagnetic free layer to invert its magnetization direction.

17. The magnetoelectric junction of claim 16, wherein the antiferromagnetic layer comprises one of: PtMn, IrMn, and combinations thereof.

18. The magnetoelectric junction of claim 17, further comprising a cap layer and a seed layer.

19. The magnetoelectric junction of claim 18, wherein at least one of the seed layer and the cap layer comprises one of: Molybdenum, Tungsten, Iridium, Bismuth, Rhenium, and Gold.

20. The magnetoelectric junction of claim 19, wherein at least one of the ferromagnetic fixed layer and the ferromagnetic free layer comprises one of: iron, nickel, manganese, cobalt, FeCoB, FeGaB, FePd, FePt, and combinations thereof.
